(19) United States
(12) Patent Application Publication
(10) Pub. No.: US 2025/0137134 A1
(43) Pub. Date: May 1, 2025

(54) CHAMBER BODIES HAVING MACHINED UPPER WALLS, CHAMBER ARRANGEMENTS AND SEMICONDUCTOR PROCESSING SYSTEMS HAVING CHAMBER BODIES WITH MACHINED UPPER WALLS, AND METHODS OF MAKING CHAMBERS WITH MACHINED UPPER WALLS

(71) Applicant: ASM IP Holding B. V., Almere (NL)

(72) Inventors: Felix Rabinovich, Scottsdale, AZ (US); Terry Parde, Chandler, AZ (US); Gary Urban Keppers, Margan Hill, CA (US); Amin Azimi, Phoenix, AZ (US); Alicia Almeda, chandler, AZ (US); Fauhmee Qudelf, Phoenix, AZ (US)

(21) Appl. No.: 18/928,393

(22) Filed: Oct. 28, 2024

Related U.S. Application Data
(60) Provisional application No. 63/546,606, filed on Oct. 31, 2023.
(60) Provisional application No. 63/546,608, filed on Oct. 31, 2023.
(60) Provisional application No. 63/546,611, filed on Oct. 31, 2023.

(51) Int. Cl. C23C 16/458; C23C 16/44; C23C 16/46

(52) U.S. Cl. CPC C23C 16/4584; C23C 16/4412; C23C 16/46

(57) ABSTRACT

A chamber body includes a ceramic weldment. The ceramic weldment has an upper wall, a sidewall, a lower wall, and a lower wall rib segment. The sidewall is coupled to the upper wall by a sidewall-to-upper wall weld, the lower wall coupled to the sidewall by a sidewall-to-lower wall weld and defining a passthrough, and the lower wall rib segment is coupled to the lower wall plate by a lower wall rib segment weld. The upper wall has an upper wall plate portion and an upper wall rib portion through that define an upper wall unwelded ribbed region, overlay the passthrough, and which is formed using a singular ceramic workpiece using a subtractive manufacturing technique. Chamber arrangements, semiconductor processing systems, and methods of making ceramic weldments are also described.

### CROSS-REFERENCE TO RELATED APPLICATIONS

This application claims priority to and the benefits of U.S. Provisional Patent Application No. 63/546,606, U.S. Provisional Patent Application No. 63/546,608, and U.S. Provisional Patent Application 63/546,611, each filed on Oct. 31, 2023, the contents each of which are also incorporated herein by reference in their entirety.

### FIELD OF INVENTION

The present disclosure generally relates to chamber bodies, and more particularly to methods of making chamber bodies, such as chamber bodies formed at least in part from ceramic materials like quartz.

### BACKGROUND OF THE DISCLOSURE

Quartz articles, such as chambers employed to deposit material layers in semiconductor processing system, are commonly formed using welding techniques. For example, cold wall chambers used for material layer deposition using chemical vapor deposition techniques generally commonly include walls bounding a process space with structural members joined to the walls with welds. The structural elements are typically welded to the walls, such as using a hydrogen gas welding technique, enabling the process space contained within the chamber walls to be maintained at relative to low pressure relative to the external environment during material layer deposition onto substrates supported within the chamber.

One challenge to employing welded quartz articles is a tendency of the welding process to introduce artifacts into the chamber weldment during fabrication. For example, gas bubbles and/or inclusions formed non-native materials may infiltrate the weldment structure during welding, potentially altering the optical properties of the weldments and/or the strength of the weldment. The localized nature of the heating employed during the welding process and subsequent cooling may impart residual stress into the weldment structure, potentially limiting strength of the weldment and increasing risk that the weldment fracture during subsequent handling and/or fabrication processes. The heat employed during the welding process may distort shape of the weldment during welding in a way that departs dimensionally from the dimensions of the intended weldment, potentially altering properties of the resulting weldment.

Various countermeasures exist to limit the introduction of artifact into weldments and/or remove artifacts from weldments subsequent to the welding process. For example, welding may be accomplished in environmentally controlled workspaces to limit contaminant introduction. The members being welded may further be cleaned prior to welding, also limiting risk that contaminant be introduced into the weldment during welding. Residual stress imparted by the welding process may be removed (at least in part) by annealing the weldment subsequent to the welding process, the uniform heating and subsequent controlled cooling limiting stress that could otherwise limit strength of the weldment. And heating of the articles being joined may be carefully controlled during the heating process to limit distortion of the shapes defined by resulting weldment, the weldment thereby more likely to satisfy the dimensional requirements of the application for which the weldment is to be employed. While generally satisfactory for its intended purpose, such techniques can add cost and complexity to the fabrication of quartz articles. For example, weldments formed from multiple welds may require multiple anneal operations due to the need to remove residual stress introduced during a prior welding operation prior to undergoing a subsequent welding operation, prolonging the fabrication process.

Such chambers and methods of making chambers using welding techniques have generally been considered suitable for their intended purpose. However, there remains a need in the art for improved chamber bodies, chamber arrangements and semiconductor processing systems including chamber bodies, and related methods of making chamber bodies. The present disclosure provides a solution to this need.

### SUMMARY OF THE DISCLOSURE

A chamber body including a ceramic weldment is provided. The ceramic weldment has an upper wall, a sidewall, a lower wall, and a lower wall rib segment. The sidewall is coupled to the upper wall by a sidewall-to-upper wall weld, the lower wall coupled to the sidewall by a sidewall-to-lower wall weld and defining a passthrough, and the lower wall rib segment is coupled to the lower wall plate by a lower wall rib segment weld. The upper wall has an upper wall plate portion and an upper wall rib portion through that define an upper wall unwelded ribbed region, overlay the passthrough, and which is formed using a singular ceramic workpiece using a subtractive manufacturing technique.

In addition to one or more of the features described above, or as an alternative, further examples of the chamber body may include that the upper wall unwelded ribbed region of the ceramic weldment is separated from the passthrough by an interior of the ceramic weldment.

In addition to one or more of the features described above, or as an alternative, further examples of the chamber body may include that the upper wall unwelded ribbed region of the ceramic weldment is separated from the passthrough by an interior of the ceramic weldment.

In addition to one or more of the features described above, or as an alternative, further examples of the chamber body may include that the ceramic weldment includes an inject end flange and an exhaust end flange. The inject end flange may be coupled to the upper wall plate portion. The exhaust end flange may be coupled to the upper wall plate portion and separated from the inject end flange by the upper wall unwelded ribbed region of the upper wall of the ceramic weldment.

In addition to one or more of the features described above, or as an alternative, further examples of the chamber body may include a tubulation body coupled to the lower wall plate at the passthrough. The tubulation body may separate the inject end flange from the exhaust end flange of the ceramic weldment.

In addition to one or more of the features described above, or as an alternative, further examples of the chamber body may include that the inject end flange and the exhaust end flange may separate the upper wall unwelded ribbed region from the lower wall rib segment of the ceramic weldment.

In addition to one or more of the features described above, or as an alternative, further examples of the chamber body may include that the lower wall rib segment is one of two or more lower wall rib segments coupled to the ceramic weldment. The ceramic weldment may further include two or more first side rib segments each arranged between the upper wall unwelded ribbed region and the plurality of lower wall rib segments and two or more second side rib segment each arranged between the upper wall unwelded ribbed region and the plurality of lower wall rib segments. The upper wall unwelded ribbed region of the ceramic weldment may separate the two or more first side rib segments from the two or more second side rib segments.

In addition to one or more of the features described above, or as an alternative, further examples of the chamber body may include two or more lower rib segment welds coupling the two or more of lower wall rib segments to the lower wall plate. The two or more lower wall rib segments may be separated from the upper wall unwelded ribbed region by the lower wall plate of the ceramic weldment.

In addition to one or more of the features described above, or as an alternative, further examples of the chamber body may include that the ceramic weldment further an inject end flange coupled to the upper wall plate portion of the upper wall by an inject end flange-to-upper wall plate portion weld and an exhaust end flange coupled to the upper wall plate portion of the upper wall by an exhaust end flange-to-upper wall plate portion weld. The upper wall unwelded ribbed region may separate the inject end flange-to-upper wall plate portion weld from the exhaust end flange-to-upper wall plate portion weld without any intervening weld therebetween.

In addition to one or more of the features described above, or as an alternative, further examples of the chamber body may include that the sidewall of the ceramic weldment is a first sidewall, the sidewall-to-upper wall weld is a first sidewall-to-upper wall plate portion weld, and that the ceramic weldment further includes a second sidewall and a second sidewall-to-upper wall plate portion weld. The second sidewall may be laterally opposite the first sidewall and separate the lower wall plate of the ceramic weldment from the upper wall of the ceramic weldment. The second sidewall-to-upper wall plate portion weld may couple the second sidewall to the upper wall plate portion. The upper wall unwelded ribbed region may separate the first sidewall-to-upper wall weld from the second sidewall-to-upper wall weld without any intervening weld therebetween.

In addition to one or more of the features described above, or as an alternative, further examples of the chamber body may include that the upper wall unwelded ribbed region of the ceramic weldment has a width that is greater than at least 300 millimeters. The ceramic weldment may consist essentially of a ceramic material such as quartz.

In addition to one or more of the features described above, or as an alternative, further examples of the chamber body may include that the upper wall unwelded ribbed of the ceramic weldment region overlays the lower wall rib segment weld of the ceramic weldment.

A chamber arrangement is provided. The chamber arrangement includes a chamber body as described wherein the upper wall unwelded ribbed region has a width that is greater than at least 300 millimeters, a divider seated within an interior of the chamber body and having a divider aperture, and a substrate support arranged within the divider aperture and supported for rotation about a rotation axis therein. The upper wall unwelded ribbed region of the ceramic weldment overlays the substrate support and the divider of the chamber arrangement.

In addition to one or more of the features described above, or as an alternative, further examples of the chamber arrangement may include a substrate pyrometer supported above the upper wall of the ceramic weldment and along a substrate pyrometer optical axis intersecting the substrate support. The upper wall unwelded ribbed region of the ceramic weldment may optically couple the substrate pyrometer to the interior of the ceramic weldment.

In addition to one or more of the features described above, or as an alternative, further examples of the chamber arrangement may include a chamber pyrometer supported above the upper wall of the ceramic weldment and along a chamber pyrometer optical axis intersecting the substrate support or the divider. The upper wall unwelded ribbed region of the ceramic weldment may be optically coupled to the chamber pyrometer.

In addition to one or more of the features described above, or as an alternative, further examples of the chamber arrangement may include two or more upper heater elements supported above the upper wall of the ceramic weldment. The upper wall unwelded ribbed region of the ceramic weldment may optically couple the upper heater elements to the substrate support or the divider of the chamber arrangement.

A semiconductor processing system is provided. The semiconductor processing system includes a chamber arrangement including a chamber body as described above wherein the upper wall unwelded ribbed region of the ceramic weldment has a width that is greater than at least 300 millimeters. A precursor source including a silicon-containing material layer precursor may be coupled to an injection end of the chamber body and an exhaust source including a vacuum pump may be coupled to an exhaust end of the chamber body and therethrough to the precursor source.

A method of making a weldment for a chamber body is provided. The method includes forming an upper wall having an upper wall plate portion and an upper wall plate portion and an upper wall rib portion extending from the upper wall plate portion from a singular ceramic workpiece using a subtractive manufacturing technique, coupling a sidewall to the upper wall with a sidewall-to-upper wall weld, coupling a lower wall plate defining a passthrough to the sidewall using a sidewall-to-lower wall weld such that the upper wall unwelded ribbed region overlays the passthrough, and coupling a lower wall rib segment to the lower wall plate using a lower wall rib segment weld.

In addition to one or more of the features described above, or as an alternative, further examples of the method may include coupling an inject end flange to the upper wall plate portion of the upper wall using an inject end flange-to-upper wall plate portion weld, coupling an exhaust end flange to the upper wall plate portion of the upper wall using an exhaust end flange-to-upper wall plate portion weld, coupling a plurality of first side rib segments to the ceramic weldment using a plurality of first side rib segment-to-ceramic weldment welds, and coupling a plurality of second side rib segments to the ceramic weldment using a plurality of second side rib segment-to-ceramic weldment welds.

In addition to one or more of the features described above, or as an alternative, further examples of the method may include registering the tubulation body to the passthrough defined within the lower wall plate and coupling the tubulation body to the lower wall plate at the passthrough using a tubulation body-to-lower wall plate weld.

In addition to one or more of the features described above, or as an alternative, further examples of the method may include that the subtractive manufacturing technique used to form the ribbed portion of the upper wall of the weldment may includes one or more of milling, core-drilling, and sawing.

In addition to one or more of the features described above, or as an alternative, a semiconductor processing system may include a chamber arrangement having a chamber body made using the above-described method.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a chamber arrangement in accordance with the present disclosure, showing material layer being deposited onto a substrate while seated within a chamber body including a ceramic weldment;

FIG. 2 is a cross-sectional side view of the chamber body of FIG. 1 according to an example of the present disclosure, showing an upper wall formed using a subtractive manufacturing technique and coupled to the ceramic weldment by welds;

FIGS. 3-6 are plan and side elevation views of the ceramic weldment of FIG. 1 according to an example of the present disclosure, showing both an upper wall unwelded ribbed region defined by subtractive manufacturing technique and welds forming the weldment;

FIG. 7 is an exploded perspective view of the ceramic weldment of FIG. 1 according to an example, showing the upper wall being formed using a subtractive technique and the parts of the ceramic weldment being coupled using a welding technique; and

FIG. 8 is a process flow diagram of a method of making a ceramic weldment for a chamber body of a semiconductor processing system, showing operations of the method according to illustrative and non-limiting examples of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

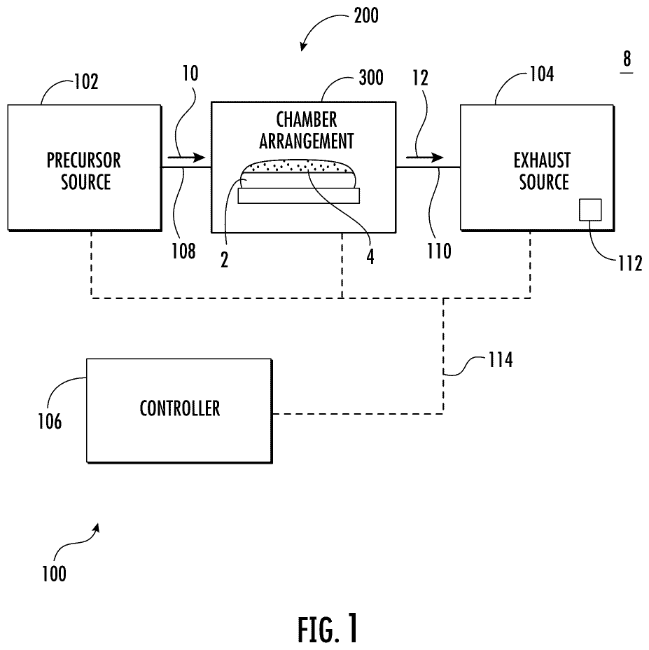

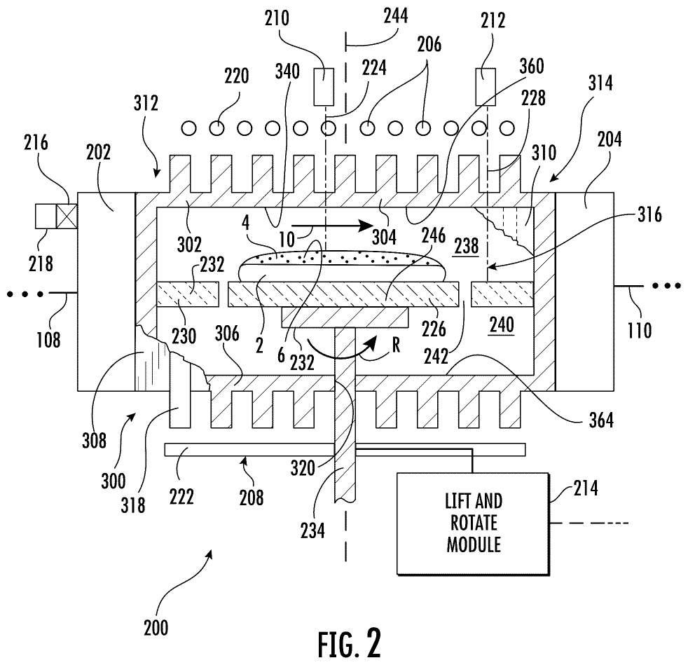

Reference will now be made to the drawings wherein like reference numerals identify similar structural features or aspects of the subject disclosure. For purposes of explanation and illustration, and not limitation, a partial view of an example of a semiconductor processing system including a chamber arrangement with a chamber body in accordance with the present disclosure is shown in FIG. 1 and is designated generally by reference character 100. Other examples of chamber bodies, chamber arrangements and semiconductor processing systems including chamber bodies in accordance with the present disclosure, and related methods a making chamber bodies and depositing material layers onto substrates supported in chamber bodies in accordance with the present disclosure, or aspects thereof, are provided in FIGS. 2-8, as will be described. The systems and methods of the present disclosure may be used to make and use chamber bodies employed to deposit material layers onto substrates, such as silicon-containing epitaxial material layers deposited using chemical vapor deposition techniques in chamber arrangements having crossflow architectures, thought the present disclosure is not limited to any particular deposition technique or chamber architecture in general.

Referring to FIG. 1, the semiconductor processing system 100 is shown. The semiconductor processing system 100 includes a precursor source 102, a chamber arrangement 200 including a chamber body 300, an exhaust source 104, and a controller 106. The precursor source 102 is connected to the chamber arrangement 200 by a precursor supply conduit 108 and is configured to provide a flow of a material layer precursor 10 to the chamber arrangement 200. The chamber arrangement 200 is connected to the exhaust source 104 and is configured to expose a substrate 2 supported within the chamber arrangement 200 to the material layer precursor 10 under environmental conditions (e.g., temperature and pressure) selected to cause a material layer 4 to deposit onto an upper surface 6 of the substrate 2. The exhaust source 104 is connected to the chamber arrangement 200 by an exhaust conduit 110, is fluidly coupled to an external environment 8 outside of the semiconductor processing system 100 (e.g., through a vacuum pump 112 and/or an abatement device such as a scrubber), and is configured to communicate a flow of residual material layer precursor and/or reaction products 12 to the external environment 8.

It is contemplated that the controller 106 may be operably connected to one or more of the precursor source 102, the chamber arrangement 200, and the exhaust source 104 to control deposition of the material layer 4 onto the substrate 2. In this respect the controller 106 may be connected to one or more of the precursor source 102, the chamber arrangement 200, and the exhaust source 104 by a wired or wireless link 114 to control temperature of the substrate 2 and/or pressure within the chamber body 300. Temperature of the substrate 2 may be controlled, for example, using heater elements and/or temperature sensors included in the chamber arrangement 200 and operatively associated and/or in communication with the controller 106. Pressure within the chamber body 300 may be controlled using the vacuum pump 112.

In certain examples, the material layer precursor 10 may include one or more silicon-containing material layer precursor. Examples of suitable silicon-containing material layer precursor include non-halogenated silicon-containing material layer precursors, such as silane (SiH₄) and disilane (Si₂H₆), and halogenated silicon-containing material layer precursors, such as dichlorosilane (H₂SiCl₂) and trichlorosilane (HCl₃Si). In accordance with certain examples, the material layer precursor 10 may include an alloying constituent, such as germanium-containing material layer precursor such as germane (GeH₄), a gallium-containing material layer precursor such as triethylgallium Ga(C₂H₅)₃, or an indium-containing material layer precursor such as trimethylindium ((CH₃)₃In). It is contemplated that, in certain examples, the material layer precursor 10 may include one or more dopant-containing material layer precursor. Examples of suitable dopant-containing material layer precursors include p-type dopants like boron (B) and arsenic (As) as well as n-type dopants such as phosphorous (P) and antimony (Sb). It is contemplated that, in accordance with certain examples, the material layer precursor 10 may be co-flowed with a diluent/carrier gas such as hydrogen (H₂) gas or nitrogen (N₂) gas and/or with an etchant, such as hydrochloric (HCl) acid or chlorine (Cl₂) gas.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the chamber arrangement 200 is shown. In the illustrated example the chamber arrangement 200 includes the chamber body 300, an injection flange 202, and an exhaust flange 204. In the illustrated example the chamber arrangement 200 also includes an upper heater element array 206, a lower heater element array 208, a substrate pyrometer 210, a chamber pyrometer 212, and a lift and rotate module 214. Although shown and described herein as having certain elements and a specific architecture, e.g., a single substrate crossflow architecture, it is to be understood and appreciated that semiconductor processing systems having chamber arrangement including other elements and/or excluding elements shows and described herein, as well as having different architectures, may also benefit from the present disclosure.

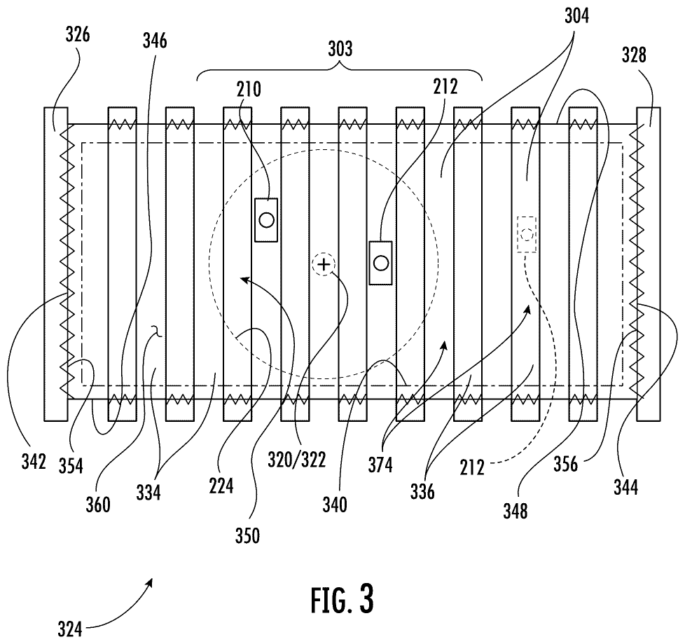

The chamber body 300 may be formed from a ceramic material 302. The chamber body 300 may include a ceramic weldment 324 (shown in FIG. 3) including an upper wall 304, a lower wall 306, a first sidewall 308, and a second sidewall 310. The upper wall 304 may extend longitudinally between an injection end 312 and a longitudinally opposite exhaust end 314 of the chamber body 300. The upper wall 304 may also have an upper wall interior surface 360 bounding an interior 316 of the chamber body 300 and/or the ceramic weldment 324. The lower wall 306 may be spaced apart from the upper wall 304 by the interior 316 of the chamber body 300. The lower wall 306 may be substantially parallel to the upper wall 304 of the chamber body 300. The first sidewall 308 may couple the lower wall 306 to the upper wall 304 of the chamber body 300.

The first sidewall 308 may extend longitudinally between the injection end 312 and the exhaust end 314 of the chamber body 300. The first sidewall 308 may be substantially orthogonal relative to either (or both) the lower wall 306 and the upper wall 304 of the chamber body 300. The second sidewall 310 may be similar to the first sidewall 308 and additionally laterally separated from the first sidewall 308 by a lateral width of the interior 316 of the chamber body 300. It is contemplated that the chamber body 300 may have a plurality of external ribs 318. The plurality of external ribs 318 may extend laterally about the exterior surfaces of the upper wall 304, the lower wall 306, the first sidewall 308 and the second sidewall 310 of the chamber body 300. The plurality of external ribs 318 may further be longitudinally spaced apart from one another along a length of the chamber body 300 between the injection end 312 and the exhaust end 314 of the chamber body 300. Although shown and described herein as having a particular number and spacing (e.g., pitch) of external ribs 318, it is to be understood and appreciated that the chamber body 300 may have fewer or additional external ribs and/or have differing spacings than shown and described herein and remain within the scope of the disclosure.

The injection flange 202 may abut the injection end 312 of the chamber body 300 and couple the precursor supply conduit 108 to the chamber body 300. The exhaust flange 204 may similarly abut the exhaust end 314 of the chamber body 300 at a location longitudinally opposite the injection flange 202, and additionally couple the chamber body 300 to the exhaust conduit 110. It is contemplated that a gate valve 216 may be coupled to the injection flange 202 and in turn couple a substrate transfer robot 218 to the chamber body 300. In certain examples, the ceramic material 302 may include a transparent material, such as a ceramic material transparent to electromagnetic radiation within an infrared waveband. In accordance with certain examples, and in this respect the chamber body 300 or the ceramic weldment 324 included in the chamber body may consist of or consist essentially of the ceramic material 302. Non-limiting examples of suitable transparent materials include quartz, fused silica and sapphire.

The upper heater element array 206 is configured to heat the substrate 2 during deposition of the material layer 4 onto the upper surface 6 of the substrate 2 (e.g., using electromagnetic radiation within an infrared waveband) and in this respect may be supported above the chamber body 300. The upper heater element array 206 may be optically coupled to the interior 316 of the chamber body 300 by the upper wall 304 of the chamber body 300 and include a plurality of upper heater elements 220. The plurality of upper heater elements 220 may each include linear filament. The plurality of upper heater elements 220 may extend laterally above the upper wall 304 of the chamber body 300 and between the first sidewall 308 and the second sidewall 310. The plurality of upper heater element 220 may be longitudinally spaced apart from one another between the injection end 312 and the exhaust end 314 of the chamber body 300.

The lower heater element array 208 may be similar to the upper heater element array 206 and additionally be supported below the chamber body 300. The lower heater element array 208 may further include a plurality of lower heater elements 222. The plurality of lower heater elements 222 may extend longitudinally between the injection end 312 and the exhaust end 314 of the chamber body 300. The plurality of lower heater elements 222 may be laterally spaced apart from one another between the first sidewall 308 and the second sidewall 310 of the chamber body 300. In certain examples, the plurality of lower heater elements 222 may be substantially orthogonal relative to the plurality of upper heater elements 220. In accordance with certain examples, either (or both) the upper heater element array 206 and the lower heater element array 208 may include bulb-type lamps and remain within the scope of the present disclosure.

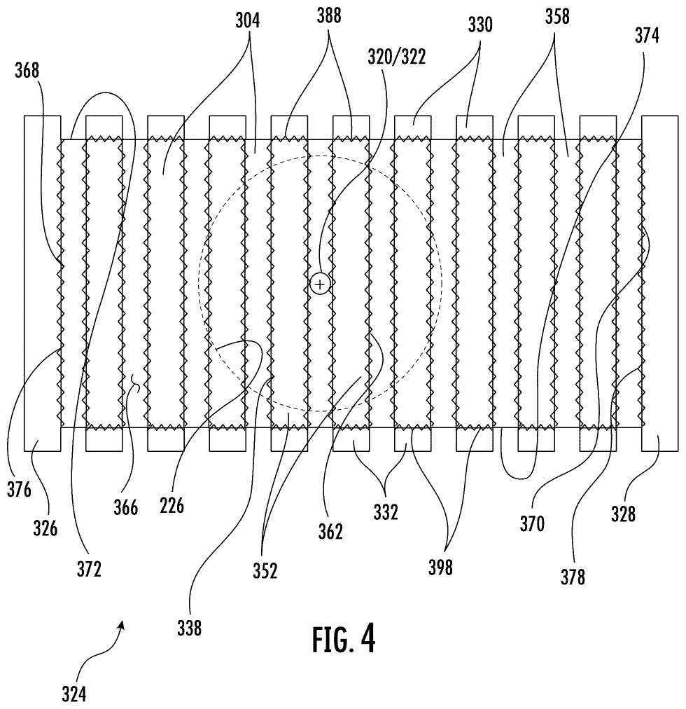

The substrate pyrometer 210 may be configured to acquire temperature measurements of the substrate 2 during deposition of the material layer 4 onto the upper surface 6 of the substrate 2 and in this respect may be supported above the chamber body 300. The substrate pyrometer 210 may be arranged along a substrate pyrometer optical axis 224. The substrate pyrometer optical axis 224 may intersect a substrate support 226 arranged within the interior 316 of the chamber body 300 and configured to seat thereon the substrate 2. The substrate pyrometer 210 may further be optically coupled to the interior 316 of the chamber body 300 by the upper wall 304 of the chamber body 300, such as by an upper wall unwelded ribbed region 340 (shown in FIG. 4), which may be weldless. The substrate pyrometer 210 may acquire temperature measurements of the substrate 2 using electromagnetic radiation emitted by either (or both) the substrate 2 and the material layer 4 during deposition onto the upper surface 6 of the substrate 2 and communicated through the ceramic material 302 forming the upper wall 304 of the chamber body 300 along the substrate pyrometer optical axis 224. In this respect the upper wall unwelded ribbed region 340 may optically couple the substrate pyrometer 210 to the interior 316 of the chamber body 300. In certain examples, the substrate pyrometer 210 may cooperate with one or more second substrate pyrometer supported above the upper wall 304 of the chamber body 300 and arranged one or more second optical axis intersecting the substrate support 226. Examples of suitable substrate pyrometers include those shown and described in U.S. Patent Application Publication No. 2022/0298672 A1 to M'Saad, filed on Mar. 17, 2022, the contents of which is incorporated herein by reference in its entirety.

The chamber pyrometer 212 may be configured to acquire temperature measurements of the chamber body 300. In this respect it is contemplated that the chamber pyrometer 212 be configured to acquire temperature measurements of the upper wall 304 of the chamber body 300 using electromagnetic radiation emitted by the upper wall 304 of the chamber body 300. The chamber pyrometer 212 may be supported above the chamber body 300 and optically coupled to the chamber body 300 by a chamber pyrometer optical axis 228. The chamber pyrometer optical axis 228 may be offset, for example longitudinally, from the substrate support 226. The chamber pyrometer optical axis 228 may be substantially parallel to the substrate pyrometer optical axis 224. It is contemplated that the chamber pyrometer 212 may be disposed in communication with the controller 106 (shown in FIG. 1), for example to control a mass flow rate of coolant circulated about the chamber body 300 to control temperature of the chamber body 300. Examples of suitable chamber pyrometers include those shown and described in U.S. Pat. No. 11,390,950 to Kim et al, issued on Jul. 19, 2022, the contents of which is incorporated herein by reference in their entirety.

The chamber arrangement 200 may include a divider 230, a support member 232, and a shaft member 234 in certain examples of the present disclosure. The divider 230 may be formed from an opaque material 236, for example a material opaque to electromagnetic radiation within an infrared waveband. The divider 230 may be seated within the interior 316 of the chamber body 300. The divider 230 may divide the interior 316 into an upper chamber 238 and a lower chamber 240. The divider 230 may further define a divider aperture 242 therethrough coupling the upper chamber 238 to the lower chamber 240. The substrate support 226 may be supported within the divider aperture 242 for rotation R about a rotation axis 244, may be formed from an opaque material 246, for example a material opaque to electromagnetic radiation within an infrared waveband. The substrate support 226 may be operably associated with the lift and rotate module 214 via the support member 232 and the shaft member 234 for rotation of the substrate 2 during deposition of the material layer 4 thereon and/or seating and unseating of the substrate 2. In this respect the support member 232 may be arranged along the rotation axis 244 and within the lower chamber 240 of the chamber body 300. The support member 232 may further be fixed in rotation relative to the substrate support 226.

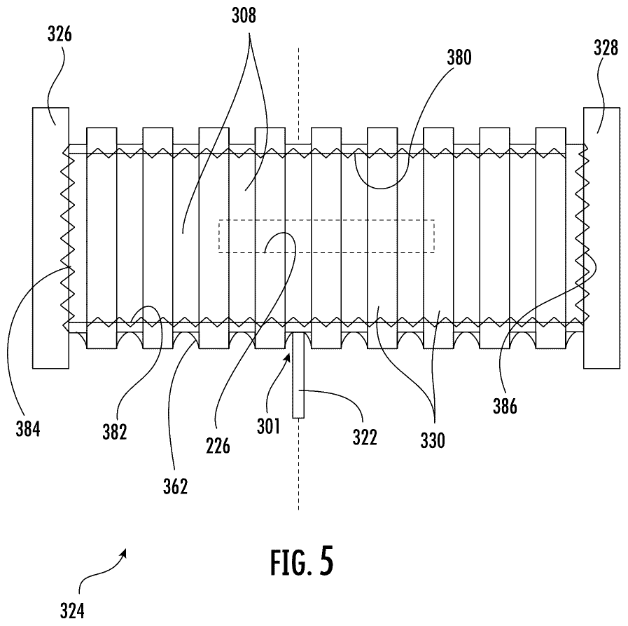

The shaft member 234 may be arranged along the rotation axis 244 extend through a passthrough 320 defined within the lower wall 306 of the chamber body 300. The shaft member 234 may be arranged within (at least in part) a tubulation body 322 (shown in FIG. 5) protruding below the lower wall 306 of the chamber body 300 and substantially coaxial with the rotation axis 244. In certain examples, the rotation axis 244 may be substantially parallel to either (or both) the substrate pyrometer optical axis 224 and the chamber pyrometer optical axis 228. In accordance with certain examples, the opaque material 236 and/or the opaque material 246 may include a carbonaceous material and/or a ceramic material. Examples of suitable carbonaceous materials include graphite and pyrolytic carbon. Examples of suitable ceramic materials include bulk silicon carbide as well as silicon carbide coatings.

As has been explained above, certain fabrication techniques employed to fabricate chamber bodies may impart artifacts into the structure of the chamber body. For example, welding techniques such as hydrogen (H₂) gas welding may impart residual stress into the weldment formed using the welding technique due to the localized nature of the heating employed to form the weld. Welding techniques may also cause the weldment to deviate dimensionally from the intended geometry of the weldment formed using the welding technique, for example by altering flatness and/or by contour of the resulting fillet formed using the welding technique. Residual stress can stress can generally be relieved using a post-welding annealing operation, albeit at the cost of additional manufacturing cycle time, generally in correspondence with the number of welds that require post-welding anneal. Dimensional deviation may be more resistant to post-welding correction, requiring that dimensional tolerances be widened to reflect the process capability of welding technique employed to fabricate the chamber body and/or greater scrap rates due to dimensional non-conformance. And even then, some material layer deposition processes may be sensitive to welding artifacts, such as welding artifacts imparted into chamber structure optically coupling external heating elements and/or temperature sensors to a substrate during processing. To limit (or eliminate) such artifacts from influence the reliability of the chamber arrangement 200, the chamber body 300 includes the ceramic weldment 324 (shown in FIG. 3).

With reference to FIGS. 3-6, the ceramic weldment 324 is shown. The ceramic weldment 324 may include the upper wall 304, the lower wall 306, the first sidewall 308, and the second sidewall 310. The ceramic weldment 324 may also include an inject end flange 326, an exhaust end flange 328 a plurality of first side rib segments 330, and a plurality of second side rib segments 332. Although shown and described herein as including specific elements and having a specific arrangement, it is to be understood and appreciated that the ceramic weldment 324 may include other elements and/or exclude elements shown and described herein, and/or have a different arrangement than shown and described herein in other examples and implementations, and remain within the scope of the present disclosure.

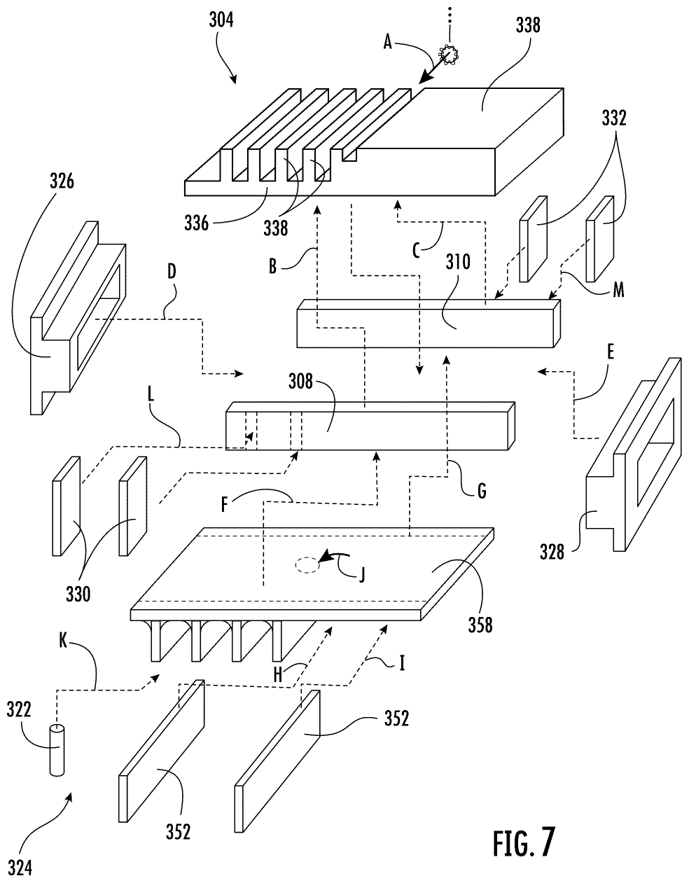

Referring to FIG. 3, a portion of the ceramic weldment 324 including the upper wall 304 is shown. The upper wall 304 may be formed from (e.g. consist of or consist essentially of) the ceramic material 302 (shown in FIG. 2) and has an upper wall plate portion 334 and an upper wall rib portion 336 extending therefrom. It is contemplated that the upper wall 304 be formed monolithically from a singular ceramic workpiece 338 (shown in FIG. 7) using a subtractive manufacturing technique (e.g., is uncast), the upper wall plate portion 334 and the upper wall rib portion 336 of the upper wall 304 thereby both defining the upper wall unwelded ribbed region 340, the upper wall 304 thereby further having a unitary, one-piece construction and be monolithically formed from the ceramic material 302. As will be appreciated by those of skill in the art in view of the present disclosure, forming the upper wall 304 using a subtractive manufacturing technique may simplify fabrication of the ceramic weldment 324, for example be eliminating welding operations otherwise required to couple rib segments to the ceramic weldment 324. Advantageously, forming the upper wall 304 using a subtractive manufacturing technique may also impart lateral stiffness into the upper wall 304 sufficient to limit (or eliminate) distortion within the ceramic weldment 324 during coupling of piece parts with welds, also simplifying fabrication of the ceramic weldment 324. To further advantage, forming the upper wall 304 may limit (or eliminate) optical effects associated with coupling piece parts to the ceramic weldment 324, such as could otherwise be present within the upper wall unwelded ribbed region 340 in examples where external devices such as upper heater element and/or pyrometers are optically coupled therethrough to the interior 316 (shown in FIG. 2) of the ceramic weldment 324. As used herein the term “unwelded ribbed region” means a unitary, one-piece, construction with no intervening welds and no welding or casting artifacts that may potentially alter the unwelded ribbed region dimensionally or in terms of optical properties.

The upper wall plate portion 334 of the upper wall 304 may have an upper wall plate portion inject edge 342, an upper wall plate portion exhaust edge 344, an upper wall plate portion first longitudinal edge 346, and an upper wall plate portion second longitudinal edge 348. The upper wall plate portion inject edge 342 may be longitudinally offset from the upper wall rib portion 336 of the upper wall 304. The upper wall plate portion exhaust edge 344 may be longitudinally opposite the upper wall plate portion inject edge 342 and separated therefrom by the upper wall rib portion 336. The upper wall plate portion inject edge 342 and the upper wall plate portion exhaust edge 344 may bound the upper wall interior surface 360 (shown in FIG. 2) of the ceramic weldment 324. The upper wall plate portion first longitudinal edge 346 and the upper wall plate portion second longitudinal edge 348 may extend longitudinally between the upper wall plate portion inject edge 342 and the upper wall plate portion exhaust edge 344. The upper wall plate portion first longitudinal edge 346 and the upper wall plate portion second longitudinal edge 348 may couple the upper wall plate portion inject edge 342 to the upper wall plate portion exhaust edge 344. In certain examples, The upper wall plate portion first longitudinal edge 346 and the upper wall plate portion second longitudinal edge 348 may be substantially orthogonal relative to either (or both) the upper wall plate portion inject edge 342 and the upper wall plate portion exhaust edge 344. In accordance with certain examples, upper wall plate portion first longitudinal edge 346 and the upper wall plate portion second longitudinal edge 348 may be parallel relative to one another.

The upper wall rib portion 336 of the upper wall 304 may define one or more upper wall rib segment, for example a plurality of upper wall rib segments 350. It is contemplated that the plurality of upper wall rib segments 350 extend laterally between the upper wall plate portion first longitudinal edge 346 and the upper wall plate portion second longitudinal edge 348. The plurality of upper wall rib segments 350 may further extend from the upper wall plate portion 334 in a direction opposite the upper wall interior surface 360 (shown in FIG. 2). The plurality of upper wall rib segments 350 may correspond (e.g., match) in number and/or longitudinal position to a plurality of lower wall rib segments 352 (shown in FIG. 4) included in the ceramic weldment 324. In certain examples, the plurality of upper wall rib segments 350 may couple the upper wall plate portion first longitudinal edge 346 to the upper wall plate portion second longitudinal edge 348 of the upper wall 304.

The upper wall unwelded ribbed region 340 may overlay the passthrough 320 defined within the lower wall 306 (shown in FIG. 2) of the ceramic weldment 324. In certain examples, the upper wall unwelded ribbed region 340 may extend about the passthrough 320. In accordance with certain examples, the upper wall unwelded ribbed region 340 may have a width 303 that is greater than about 300 millimeters. As will be appreciated by those of skill in the art in view of the present disclosure, sizing the upper wall unwelded ribbed region 340 to be at least 300 millimeters may limit effects potentially caused by welding artifacts in both heating of the substrate 2 (shown in FIG. 2) using the upper heater element array 206 (shown in FIG. 2) and/or temperature measurements acquired using the substrate pyrometer 210 as well as the chamber pyrometer 212, improving control of the deposition process employed to deposit the material layer 4 (shown in FIG. 1) onto the substrate 2 by limiting temperature variation across the substrate 2 during deposition.

The inject end flange 326 is configured to receive thereon the injection flange 202 (shown in FIG. 2) and may be formed from (e.g., consist of or consist essentially of) the ceramic material 302 (shown in FIG. 2). The inject end flange 326 may be longitudinally adjacent to the upper wall plate portion 334 of the upper wall 304. The inject end flange 326 may be separated from the upper wall plate portion exhaust edge 344 by the upper wall rib portion 336. The inject end flange 326 may be coupled to the upper wall 304 by an inject end flange-to-upper wall plate portion weld 354. The inject end flange-to-upper wall plate portion weld 354 may in turn extend laterally along the upper wall plate portion inject edge 342. The inject end flange-to-upper wall plate portion weld 354 may extend laterally between the first sidewall 308 (shown in FIG. 2) and the second sidewall 310 (shown in FIG. 2). The inject end flange-to-upper wall plate portion weld 354 may extend continuously and without interruption between the first sidewall 308 and the second sidewall 310. As used herein the term “weld” means a thermal bond, link or structure that joins two elements through a process that involves a softening or melting of a ceramic material within at least one of the elements such that the materials of the elements are secured to each other when cooled, the welded elements thereby being structurally secured to one another as a consequence of the cooling.

The exhaust end flange 328 is configured to receive thereon the exhaust flange 204 (shown in FIG. 2) and may similarly be formed from (e.g., consist of or consist essentially of) the ceramic material 302 (shown in FIG. 2). The exhaust end flange 328 may be longitudinally adjacent to the upper wall plate portion 334 of the upper wall 304. The exhaust end flange 328 may be separated from the upper wall plate portion exhaust edge 344 by the upper wall rib portion 336 of the upper wall 304. The exhaust end flange 328 may be longitudinally opposite the inject end flange 326. It is contemplated that the exhaust end flange 328 be coupled to the upper wall plate portion 334 by an exhaust end flange-to-upper wall plate portion weld 356. The exhaust end flange-to-upper wall plate portion weld 356 may in turn extend laterally along the upper wall plate portion exhaust edge 344. The exhaust end flange-to-upper wall plate portion weld 356 may extend laterally between the first sidewall 308 and the second sidewall 310. In certain examples, the exhaust end flange-to-upper wall plate portion weld 356 may extend continuously and without interruption between the first sidewall 308 and the second sidewall 310. In accordance with certain examples, the upper wall unwelded ribbed region 340 may extend continuously and without interruption (e.g., without any intervening welds) between the inject end flange-to-upper wall plate portion weld 354 and the exhaust end flange-to-upper wall plate portion weld 356.

Referring to FIG. 4, a portion of the ceramic weldment 324 including the lower wall 306 is shown. The lower wall 306 may be formed from (e.g., consist of or consist essentially of) the ceramic material 302 (shown in FIG. 2). The lower wall 306 may include a lower wall plate 358 and one or more lower rib segment, for example a plurality of lower wall rib segments 352. The lower wall plate 358 has a lower wall interior surface 364 (shown in FIG. 2) and a lower wall exterior surface 366, which may be separated from one another by a thickness of the lower wall plate 358. The lower wall plate 358 may further have a lower wall plate inject edge 368, an lower wall plate exhaust edge 370, a lower wall plate first longitudinal edge 372, and a lower wall plate second longitudinal edge 374. The lower wall interior surface 364 may be substantially planar, extend longitudinally between the lower wall plate inject edge 368 and the lower wall plate exhaust edge 370, and further extend laterally between the lower wall plate first longitudinal edge 372 and the lower wall plate second longitudinal edge 374. The lower wall exterior surface 366 may be substantially planar in shape and extend longitudinally between the lower wall plate inject edge 368 and the lower wall plate exhaust edge 370. The lower wall exterior surface 366 may extend laterally between the lower wall plate first longitudinal edge 372 and the lower wall plate second longitudinal edge 374 of the lower wall plate 358.

In certain examples, the lower wall plate exhaust edge 370 may be substantially parallel to the lower wall plate inject edge 368 of the lower wall plate 358. The lower wall plate second longitudinal edge 374 may be substantially parallel to the lower wall plate first longitudinal edge 372. In certain examples, the lower wall plate first longitudinal edge 372 may be substantially orthogonal relative to either (or both) the lower wall plate inject edge 368 and the lower wall plate exhaust edge 370. In accordance with certain examples, the lower wall plate second longitudinal edge 374 may be substantially orthogonal relative to either (or both) the lower wall plate inject edge 368 and the lower wall plate exhaust edge 370.

The plurality of lower wall rib segments 352 may be formed from (e.g., consist of or consist essentially of) the ceramic material 302 (shown in FIG. 2). The plurality of lower wall rib segments 352 may be coupled to the lower wall exterior surface 366 by a plurality of lower wall rib segment welds 362. The plurality of lower wall rib segments 352 extend laterally between the lower wall plate first longitudinal edge 372 and the lower wall plate second longitudinal edge 374 of the lower wall plate 358. In certain examples, the plurality of lower wall rib segments 352 may be substantially orthogonal relative to the lower wall plate first longitudinal edge 372 and/or the lower wall plate second longitudinal edge 374. In accordance with certain examples, the plurality of lower wall rib segments 352 may be substantially parallel to the lower wall plate inject edge 368 and/or the lower wall plate exhaust edge 370 of the lower wall plate 358. In certain examples, the plurality of lower wall rib segments 352 may couple (e.g., laterally span) the lower wall plate first longitudinal edge 372 to the lower wall plate second longitudinal edge 374 of the lower wall plate 358.

It is contemplated that the inject end flange 326 may be coupled to the lower wall plate inject edge 368 by an inject end flange-to-lower wall plate weld 376. The inject end flange-to-lower wall plate weld 376 may extend between the lower wall plate first longitudinal edge 372 and the lower wall plate second longitudinal edge 374 of the lower wall plate 358. In certain examples, the inject end flange-to-lower wall plate weld 376 may extend continuously and without interruption between the lower wall plate first longitudinal edge 372 and the lower wall plate second longitudinal edge 374 of the lower wall plate 358.

It is also contemplated that the exhaust end flange 328 may be coupled to the lower wall plate exhaust edge 370 of the lower wall plate 358. In this respect the exhaust end flange 328 may be coupled to the lower wall plate 358 by an exhaust end flange-to-lower wall plate weld 378. The exhaust end flange-to-lower wall plate weld 378 may extend between the lower wall plate first longitudinal edge 372 and the lower wall plate second longitudinal edge 374. In certain examples, the exhaust end flange-to-lower wall plate weld 378 may extend continuously and without interruption between the lower wall plate first longitudinal edge 372 and the lower wall plate second longitudinal edge 374 of the lower wall plate 358.

Referring to FIG. 5, a portion of the ceramic weldment 324 including the first sidewall 308 is shown. The first sidewall 308 may be formed from (e.g., consist of or consist essentially of) the ceramic material 302 (shown in FIG. 2). The first sidewall 308 may further couple the upper wall 304 (shown in FIG. 2) of the ceramic weldment 324 to the lower wall 306 (shown in FIG. 2) of the ceramic weldment 324. More specifically, the first sidewall 308 may couple the upper wall plate portion 334 (shown in FIG. 2) of the upper wall 304 to the lower wall 306 of the ceramic weldment 324. Specifically, the first sidewall 308 may couple the upper wall plate portion 334 of the upper wall 304 to the lower wall plate 358 (shown in FIG. 3) of the lower wall 306. It is contemplated that the first sidewall 308 may be coupled to the upper wall plate portion 334 by a first sidewall-to-upper wall plate portion weld 380. It is also contemplated that the first sidewall 308 may be coupled to the lower wall plate 358 by a first sidewall-to-lower wall plate weld 382. The first sidewall-to-upper wall plate portion weld 380 may extend continuously and without interruption between the inject end flange-to-upper wall plate portion weld 34 and the exhaust end flange-to-upper wall plate portion weld 356. In certain examples, the first sidewall-to-lower wall plate weld 382 may extend continuously and within interruption between the inject end flange-to-lower wall plate weld 376 and the exhaust end flange-to-lower wall plate weld 378.

The inject end flange 326 and the exhaust end flange 328 be coupled by the first sidewall 308 by welds. In this respect the inject end flange 326 may be coupled to the first sidewall 308 by an inject end flange-to-first sidewall weld 384. In further respect, the exhaust end flange 328 may be coupled to the first sidewall 308 by an exhaust end flange-to-first sidewall weld 386. The exhaust end flange-to-first sidewall weld 386 may be longitudinally separated from the inject end flange-to-first sidewall weld 384 by the tubulation body 322. In certain examples, the inject end flange-to-first sidewall weld 384 may extend continuously and without interruption longitudinally between the inject end flange-to-lower wall plate weld 376 and the inject end flange-to-upper wall plate portion weld 354. In accordance with certain examples, the exhaust end flange-to-first sidewall weld 386 may extend continuously and without interruption between the exhaust end flange-to-lower wall plate weld 378 and the exhaust end flange-to-upper wall plate portion weld 356. It is contemplated that the tubulation body 322 may include (or consist of or consist essentially of) the ceramic material 302 (shown in FIG. 2).

The plurality of first side rib segments 330 be coupled to the ceramic weldment 324 by a plurality of first side rib segment-to-ceramic weldment welds 388 (shown in FIG. 3). In this respect it is contemplated that each of the of first side rib segment-to-ceramic weldment welds 388 may couple a respective one of the plurality of first side rib segments 330 to the ceramic weldment 324. In further respect, one or more of the plurality of first side rib segments 330 extend between and a respective one of the plurality of lower wall rib segments 352 (shown in FIG. 3) to a respective one of the plurality of upper wall rib segments 350. In these respects it is contemplated that the plurality of first side rib segments 330 cooperate with the plurality of upper wall rib segments 350 defined by the upper wall rib portion 336 of the upper wall 304 and the plurality of lower wall rib segments 352 coupled to the lower wall plate 358 of the lower wall 306 to form the plurality of external ribs 318 (shown in FIG. 2) extending about the chamber body 300 (shown in FIG. 1). In certain examples the plurality of first side rib segment-to-ceramic weldment welds 388 may be as shown and described in U.S. patent application Ser. No. 99/999,999, filed on DATE, the contents of which is incorporated herein by reference in its entirety.

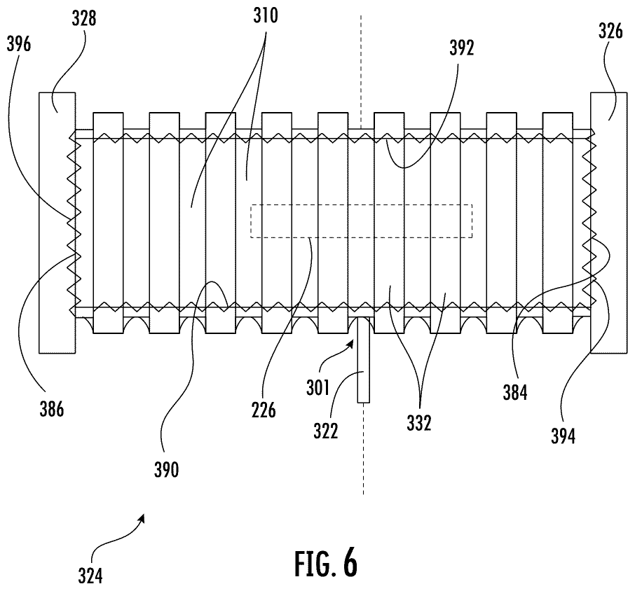

Referring to FIG. 6, a portion of the ceramic weldment 324 including the second sidewall 310 is shown in another side elevation view. The second sidewall 310 may be similar to the first sidewall 308 (shown in FIG. 2) and in this respect may similarly couple the upper wall 304 (shown in FIG. 2) of the ceramic weldment 324 to the lower wall 306 (shown in FIG. 2) of the ceramic weldment 324. More specifically, the second sidewall 310 may couple the upper wall plate portion 334 (shown in FIG. 4) of the upper wall 304 of the ceramic weldment 324 to the lower wall 306 of the ceramic weldment 324. Specifically, the second sidewall 310 may couple the upper wall plate portion 334 of the upper wall 304 to the lower wall plate 358 (shown in FIG. 3) of the lower wall 306 of the ceramic weldment 324. In further respect, the second sidewall 310 may be formed from (e.g., consist of or consist essentially of) the ceramic material 302 (shown in FIG. 2).

It is contemplated that coupling of upper wall 304 to the lower wall 306 by the second sidewall 310 may be accomplished by a second sidewall-to-lower wall plate weld 390. The second sidewall-to-lower wall plate weld 390 may extend in parallel with the first sidewall-to-lower wall plate weld 382 (shown in FIG. 5). The second sidewall-to-lower wall plate weld 390 may extend in parallel with the first sidewall-to-upper wall plate portion weld 380 (shown in FIG. 5). In certain examples, the second sidewall-to-lower wall plate weld 390 may extend continuously and without interruption longitudinally between the inject end flange-to-lower wall plate weld 376 (shown in FIG. 4) to the exhaust end flange-to-lower wall plate weld 378 (shown in FIG. 4). It is contemplated that coupling of the upper wall 304 to the lower wall 306 by the second sidewall 310 may be further accomplished by a second sidewall-to-upper wall plate portion weld 392. The second sidewall-to-upper wall plate portion weld 392 may extend in parallel with the second sidewall-to-lower wall plate weld 390. In certain examples the second sidewall-to-upper wall plate portion weld 392 may extend continuously and without interruption between the inject end flange-to-upper wall plate portion weld 354 and the exhaust end flange-to-upper wall plate portion weld 356. In accordance with certain examples, the upper wall unwelded ribbed region 340 (shown in FIG. 3) of the upper wall 304 (shown in FIG. 2) may extend continuously and without interruption between the first sidewall-to-upper wall plate portion weld 380 (shown in FIG. 5) and the second sidewall-to-upper wall plate portion weld 392.

The inject end flange 326 and the exhaust end flange 328 may be coupled to the second sidewall 310 by welds. In this respect the inject end flange 326 may be coupled to the second sidewall 310 by an inject end flange-to-second sidewall weld 394. In further respect the exhaust end flange 328 may be coupled to the second sidewall 310 by an exhaust end flange-to-second sidewall weld 396. The inject end flange-to-second sidewall weld 394 and the exhaust end flange-to-second sidewall weld 396 may be similar to the inject end flange-to-first sidewall weld 384 and the exhaust end flange-to-first sidewall weld 386, respectively, the inject end flange-to-second sidewall weld 394 being substantially parallel to the inject end flange-to-first sidewall weld 384 and the exhaust end flange-to-second sidewall weld 396 being substantially parallel to the exhaust end flange-to-first sidewall weld 386. Advantageously, the dimensional conformity imparted to the upper wall 304 by the subtractive manufacturing process used to form the upper wall 304 of the ceramic weldment 324 may also limit skew of the aforementioned welds to one another, also improving yield of the process used to fabricate the ceramic weldment 324.

The plurality of second side rib segments 332 may be similar to the plurality of first side rib segments 330 (shown in FIG. 5) and this respect may be coupled to the ceramic weldment 324 by a plurality of second side rib segment-to-ceramic weldment welds 398 (shown in FIG. 4). In this respect it is contemplated that each of the plurality of second side rib segments 332 may cooperate with individual ones of the plurality of lower wall rib segments 352, the plurality of upper wall rib segments 350, and the plurality of first side rib segments 330 to form the external ribs 318 (shown in FIG. 2) of the chamber body 300 (shown in FIG. 1). As above, the dimensional conformity imparted into the upper wall 304 of the ceramic weldment 324 by the subtractive manufacturing process employed to form the upper wall 304 of the ceramic weldment 324 may limit (or eliminate) likelihood of misalignment of the rib segments forming any one of the plurality of external ribs 318, improving yield of the manufacturing process employed to fabricate the ceramic weldment 324. As will be appreciated by those of skill in the art in view of the present disclosure, limiting likelihood of misalignment can also improve yield of the process employed to fabricate the ceramic weldment 324 as will reduce skill level of the fabricators employed to fabricate the ceramic weldment, limiting cost and reducing time required to fabricate the ceramic weldment 324.

With reference to FIG. 7, the ceramic weldment 324 is shown being assembled in an exploded view. As shown with arrow A, it is contemplated that the upper wall 304 be formed from the singular ceramic workpiece 338 using a subtractive manufacturing technique. In this respect it is contemplated that material be removed from a monolithic ceramic workpiece, e.g., a quartz workpiece, to define both the upper wall plate portion 334 and the upper wall rib portion 336 without coupling an upper rib to the upper wall 304 using a welding technique. In certain examples, the upper wall 304 may be formed using a machining operation. Examples of suitable machining operations that may be employed to from the upper wall 304 include milling, grinding, cutting and lapping as well as using certain rotary, abrasive tools. Advantageously, forming the upper wall 304 using the subtractive technique may limit time required to fabricate the ceramic weldment 324, improve yield of the process employed to fabricate the ceramic weldment 324, and/or limit the requisite skill level of the fabricators employed to fabricate the ceramic weldment 324. As will be appreciated by those of skill of the art in view of the present disclosure, this can limit cost of the ceramic weldment 324 and/or limit the cycle time associated with the fabrication of the ceramic weldment 324. The subtractive manufacturing technique used to form the ribbed portion of the upper wall of the weldment may include one or more of milling, core-drilling, and sawing.

As shown with arrows B and C, the first sidewall 308 and the second sidewall 310 may be coupled to the upper wall 304 using welds. In this respect it is contemplated that the first sidewall 308 be registered to the upper wall interior surface 360 at a location proximate the upper wall plate portion first longitudinal edge 346 (shown in FIG. 3). Once registered, the first sidewall-to-upper wall plate portion weld 380 (shown in FIG. 5) may be formed to couple the first sidewall 308 to the upper wall 304 of the ceramic weldment 324. It is contemplated that the first sidewall-to-upper wall plate portion weld 380 may be formed longitudinally between the upper wall plate portion inject edge 342 (shown in FIG. 3) and the upper wall plate portion exhaust edge 344 (shown in FIG. 3). The second sidewall 310 may similarly registered to the upper wall interior surface 360 (shown in FIG. 2) at a location proximate the upper wall plate portion second longitudinal edge 348. The second sidewall-to-upper wall plate portion weld 392 may then be formed at a location longitudinally between the upper wall plate portion inject edge 342 and the upper wall plate portion exhaust edge 344.

As shown with arrow D and arrow E, the inject end flange 326 and the exhaust end flange 328 may be coupled to the ceramic weldment 324 using a welding technique. In this respect it is contemplated that the inject end flange 326 may be registered to the upper wall plate portion inject edge 342 (shown in FIG. 3) of the upper wall plate portion 334 of the upper wall 304. Once registered, the inject end flange 326 may be coupled to the ceramic weldment 324 by forming the inject end flange-to-upper wall plate portion weld 354 (shown in FIG. 3) between the upper wall plate portion inject edge 342 and the inject end flange 326. The inject end flange 326 may further coupled to the first sidewall 308 by forming the inject end flange-to-first sidewall weld 384 (shown in FIG. 5) between the first sidewall 308 and the inject end flange 326, and further forming the inject end flange-to-second sidewall weld 394 (shown in FIG. 6) weld between the second sidewall 310 and the inject end flange 326. The exhaust end flange 328 may similarly be registered to the upper wall plate portion exhaust edge 344 (shown in FIG. 3) of the upper wall plate portion 334 of the upper wall 304, the exhaust end flange-to-upper wall plate portion weld 356 (shown in FIG. 3) formed between the exhaust end flange 328 and the upper wall plate portion exhaust edge 344, and the exhaust end flange-to-first sidewall weld 386 (shown in FIG. 5) and the exhaust end flange-to-second sidewall weld 396 (shown in FIG. 6) formed between the exhaust end flange 328 and the first sidewall 308 and the second sidewall 310, respectively.

As shown with arrow F and arrow G, the lower wall plate 358 may be coupled to the ceramic weldment 324 registering the lower wall plate 358 to one or more of the first sidewall 308, the second sidewall 310, the inject end flange 326 and the exhaust end flange 328. Once registered, welds may formed between the lower wall plate 358 and the ceramic weldment 324. In this respect it is contemplated that the first sidewall-to-lower wall plate weld 382 (shown in FIG.) be formed between the lower wall plate 358 and the first sidewall 308 (shown in FIG. 5). In further respect, the second sidewall-to-lower wall plate weld 390 (shown in FIG. 6) may be formed between the lower wall plate 358 and the second sidewall 310, the inject end flange-to-lower wall plate weld 376 (shown in FIG. 4) may be formed between the inject end flange 326 and the lower wall plate inject edge 368 (shown in FIG. 4), and the exhaust end flange-to-lower wall plate weld 378 (shown in FIG. 4) formed between the exhaust end flange 328 and the lower wall plate exhaust edge 370 (shown in FIG. 4). Advantageously, the aforementioned dimensional stability (e.g., resistance to deformation associated with localized heating) provided by the subtractive manufacturing technique employed to form the upper wall 304 may simplify formation of the weld coupling the lower wall plate 358 to the ceramic weldment 324, for example limiting (or eliminating) the need to remove native material to effect registration and/or fill gaps associated with dimensional changes.

Once the lower wall plate 358 has been coupled to the ceramic weldment 324, the plurality of lower wall rib segments 352 may be coupled to the lower wall plate 358. In this respect, as shown with arrow H and arrow I, the plurality of lower wall rib segments 352 may be sequentially registered to the ceramic weldment 324 and the plurality of lower wall rib segment welds 362 (shown in FIG. 4) formed between each of the respective lower wall rib segments 352 and the lower wall plate 358. Registration may be accomplished at positions underlying the upper wall rib portion 336 of the upper wall 304, the upper wall rib portion 336 serving as a template to inform a fabricator as to where any one of the plurality of lower wall rib segments 352 should be positioned prior to welding. The upper wall rib portion 336 may further serve as post-welding indicator of whether the intended position of any one of the plurality of lower wall rib segments 352 was positionally disturbed by the forming of one or more of the plurality of lower wall rib segment welds 362. As will be appreciated by those of skill in the art in view of the present disclosure, employment of the upper wall 304 as go/no-go gauge may can further limit variation within the ceramic weldment 324 with respect to predetermined position of each of the lower wall rib segments 352 due to aforementioned lateral stiffness of the upper wall 304, also improving yield of the manufacturing process employed to fabricate the ceramic weldment 324.

As shown with arrow J, the passthrough 320 may be defined within the lower wall 306 using a drilling operation at a location between two (2) longitudinally adjacent ones of the plurality of upper wall rib segments 350 (shown in FIG. 4). The passthrough 320 may be defined at location whereat the upper wall unwelded ribbed region 340 (shown in FIG. 3) overlays the passthrough 320 and extends thereabout. Once the passthrough 320 is defined, the tubulation body 322 may be registered to the passthrough 320 and the tubulation body-to-lower wall plate weld 301 (shown in FIG. 4) formed between the tubulation body 322 and the lower wall plate 358, as also shown with arrow K. As will be appreciated by those of skill in the art in view of the present disclosure, the subtractive manufacturing process employed to form the lower wall 306 may simplify either (or both) the forming of the passthrough 320 and the forming of the tubulation body-to-lower wall plate weld 301 (shown in FIG. 5) due to stiffness imparted to the upper wall 304 by the unitary, one-piece construction of the upper wall 304 as well as the dimensional stability by absence of welds between the plurality of upper wall rib segments 350 and the upper wall plate portion 334 of the lower wall 306.

As shown with arrow L and arrow M, coupling of the plurality of first side rib segments 330 and the plurality of second side rib segments 332 may be accomplished by registering each of the plurality of first side rib segments 330 to the ceramic weldment 324 at locations where each spans a respective one of the plurality of upper wall rib segments 350 of the upper wall 304 and an underlying respective one of the plurality of lower wall rib segments 352. Once registered, a respective one of the plurality of first side rib segment-to-ceramic weldment welds 388 may be formed between the one of the plurality of first side rib segments 330 and the ceramic weldment 324, and aforementioned register and weld operation repeated to sequentially couple each of the plurality of first side rib segments 330 to the ceramic weldment 324. Coupling of the plurality of second side rib segments 332 may similarly be accomplished by registering each of the plurality of second side rib segments 332 at a location where each spans a respective one of the plurality of upper wall rib segments 350 and respective one of the plurality of lower wall rib segments 352, and thereafter forming a respective one of the plurality of second side rib segment-to-ceramic weldment welds 398 therebetween. Notably, the above-described templating and associated improvement in process capability with respect to position of the plurality of upper wall rib segments 350 attributable to the subtractive manufacturing process employed to form the upper wall 304 may also simplify fabrication of the ceramic weldment 324, improving yield and/or reducing the requisite skill level of the fabricator assembling the ceramic weldment 324.

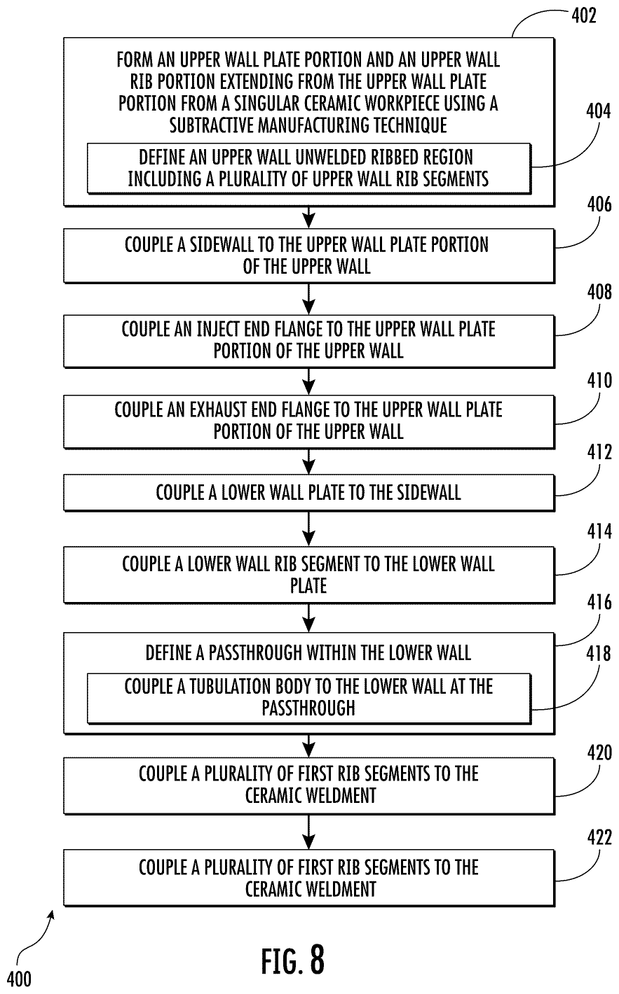

With reference to FIG. 8, a method 400 of making a ceramic weldment, e.g., the ceramic weldment 324 (shown in FIG. 2), is shown. The method 400 generally includes forming an upper wall having an upper wall plate portion and an upper wall ribbed portion extending therefrom using a subtractive manufacturing technique, e.g., the upper wall 304 (shown in FIG. 2) having the upper wall plate portion 334 (shown in FIG. 4) and the upper wall rib portion 336 (shown in FIG. 4), as shown with box 402. It is contemplated that the upper wall be formed using a subtractive manufacturing technique, the subtractive manufacturing technique defining an upper wall unwelded ribbed region along the upper wall, e.g., the upper wall unwelded ribbed region 340 (shown in FIG. 4), as shown with box 404. Advantageously, forming the upper wall using the subtractive manufacturing technique may improve time required for fabrication of the ceramic weldment by avoiding the need to couple upper wall rib segments to the ceramic weldment. To further advantage, forming the upper wall using the subtractive manufacturing technique may also limit the requisite skill level of personnel employed to fabricate the ceramic weldment, for example by substituting (at least in part) the repeatability and precision of a computer numerical control process for the experience of an individual skilled welding ceramic material. Unexpectedly, applicant has also found that material layers deposited within ceramic weldments having unwelded ribbed regions may also exhibit less within-material layer variation, believed to be attributable to absence of welding artifacts and distortions within ceramic chambers having welded ribbed regions coupling heater elements and/or optical temperature sensors to the interior of the ceramic weldment. Non-limiting examples of suitable subtractive manufacturing techniques that may be employed to form the ceramic weldment include milling, grinding, lapping and cutting.

The method 400 may include coupling a sidewall to the upper wall plate portion of the ceramic weldment, e.g., the first sidewall 308 (shown in FIG. 2) and the second sidewall 310 (shown in FIG. 2), as shown with box 406. The first sidewall may be coupled to the lower wall using a welding technique by forming a first sidewall-to-upper wall plate portion weld, e.g., the first sidewall-to-upper wall plate portion weld 380 (shown in FIG. 5), as also shown with box 406. The second sidewall may be coupled to the upper wall plate portion using the welding technique by forming a second sidewall-to-upper wall plate portion weld, e.g., the second sidewall-to-upper wall plate portion weld 392 (shown in FIG. 6), as further shown with box 406. The first sidewall-to-lower wall plate portion weld and/or the second sidewall-to-lower wall plate portion weld may be formed using a hydrogen (H₂) gas welding technique, as further shown with box 406.

In certain examples, the method 400 may include coupling an inject end flange and an exhaust end flange to the ceramic weldment, e.g., the inject end flange 326 (shown in FIG. 3) and the exhaust end flange 328 (shown in FIG. 3), as shown with box 408 and box 410. In this respect the inject end flange may be coupled to the upper wall plate portion by forming an inject end flange-to-upper wall plate portion weld using a welding technique, e.g., the inject end flange-to-upper wall plate portion weld 354 (shown in FIG. 3), as also shown with box 408. The inject end flange may further be coupled to the first sidewall and the second sidewall by forming an inject end flange-to-first sidewall weld and an inject end flange-to-second sidewall weld using the welding technique, e.g., the inject end flange-to-first sidewall weld 384 (shown in FIG. 5) and the inject end flange-to-second sidewall weld 394 (shown in FIG. 6), as further shown with box 408.

The exhaust end flange may be coupled to the lower wall plate portion by forming an exhaust end flange-to-lower wall weld using a welding technique, e.g., the exhaust end flange-to-lower wall plate weld 378 (shown in FIG. 3), as also shown with box 410. The exhaust end flange may further be coupled to the first sidewall and the second sidewall by forming an exhaust end flange-to-first sidewall weld and an exhaust end flange-to-second sidewall weld using the welding technique, e.g., the exhaust end flange-to-first sidewall weld 386 (shown in FIG. 5) and the exhaust end flange-to-second sidewall weld 396 (shown in FIG. 6), as further shown with box 410. It is contemplated that one or more of the welds coupling the inject end flange and the exhaust end flange to the ceramic weldment may be formed using a hydrogen (H₂) gas welding technique.

The method 400 may additionally include coupling a lower wall plate to ceramic weldment, e.g., the lower wall plate 358 (shown in FIG. 3), as shown with box 412. In this respect it is contemplated that the lower wall plate be coupled to a sidewall of the ceramic weldment, for either or both the first sidewall and the second sidewall, as also shown with box 412. Coupling the lower wall plate to the ceramic weldment may include forming a first sidewall-to-lower wall plate weld and a second sidewall-to-lower wall plate weld using a welding technique, e.g., the first sidewall-to-lower wall plate weld 382 (shown in FIG. 3) and the second sidewall-to-lower wall plate weld 39 (shown in FIG. 4), as further shown with box 412. Coupling the lower wall plate to the ceramic weldment may additionally include forming an inject end flange-to-lower wall plate weld and an exhaust end flange-to-lower wall plate weld using a welding technique, e.g., the exhaust end flange-to-lower wall plate weld 378 (shown in FIG. 4) and the exhaust end flange-to-lower wall plate weld 378 (shown in FIG. 4), as further shown with box 412. Either or both the first sidewall-to-lower wall plate weld and the second sidewall-to-lower wall plate weld may be formed using a hydrogen (H₂) gas welding technique.

It is also contemplated that the method 400 may include coupling a plurality of lower wall rib segments to the ceramic weldment, e.g., the plurality of lower wall rib segments 352 (shown in FIG. 3), as shown with box 414. The plurality of lower wall rib segments may be coupled to the lower wall plate by a plurality of lower wall rib segment welds formed using a welding technique, e.g., the plurality of lower wall rib segment welds 362 (shown in FIG. 3) as also shown with box 414. It is contemplated that the method 400 include defining a passthrough within the lower wall plate of the ceramic weldment, e.g., the passthrough 320 (shown in FIG. 2), as shown with box 416. Once the passthrough is formed, a tubulation body may registered to the passthrough (e.g., such that the tubulation body extends thereabout), and thereafter coupled to the lower wall at the passthrough, as also shown with box 414. It is also contemplated that the tubulation body be coupled to the lower wall plate portion using a tubulation body-to-lower wall plate weld, e.g., the tubulation body-to-lower wall plate weld 301 (shown in FIG. 5), as shown with box 418. The tubulation body-to-lower wall plate portion weld may be formed using a hydrogen (H₂) gas welding technique, as also shown with box 418.

In certain examples, the method 400 may also include coupling a plurality of first side rib segments to the ceramic weldment, e.g., the plurality of first side rib segments 330 (shown in FIG. 3), as shown with box 420. In this respect the plurality of first side rib segments may be coupled to the weldment by a plurality of first side rib segment-to-ceramic weldment welds, e.g., using the plurality of first side rib segment-to-ceramic weldment welds 388 (shown in FIG. 3), as also shown with box 420. In accordance with certain examples, the method 400 may further include coupling a plurality of second side rib segments to ceramic weldment, the plurality of second side rib segments 332 (shown in FIG. 3), as shown with box 422. In such examples the plurality of second side rib segments may be coupled to the weldment by a plurality of second side rib segment-to-ceramic weldment welds formed using a welding technique, e.g., using the plurality of second side rib segment-to-ceramic weldment welds 398 (shown in FIG. 3), as also shown with box 422. As above, one or more of plurality of first side rib segment-to-ceramic weldment welds and the plurality of second side rib segment-to-ceramic weldment welds may be formed using a hydrogen (H₂) gas welding technique, as also shown with box 420 and box 422.

Ceramic weldments for chamber bodies may be formed by coupling discrete piece parts to from the ceramic weldment. While generally satisfactory for its intended purpose, welding can be time consuming and may require specialized skill and experience, for example in ceramic weldments where exterior ribs are employed to provide structural support where the ceramic weldment is evacuated due use. Welding also may also entail post-weld annealing to remove residual stress from the ceramic weldment associated with the welding process, adding time and cost the fabrication process. Welding may further introduce dimensional variation and/or variation into the optical properties of the ceramic, potentially limiting yield of the fabrication process employed to make the ceramic weldment and/or, in the case of ceramic weldments employed to deposit material layers onto substrates, induce variation into the material layer due to the influence of the optical variation on the performance of external devices optically coupled through walls of the ceramic weldment.

In examples of the present disclosure, an upper wall of the ceramic weldment is formed using a subtractive manufacturing technique. Forming the upper wall of the ceramic weldment using the subtractive manufacturing technique may limit time required to fabricate the ceramic weldment, for example by limiting time required to otherwise weld discrete piece-part upper rib segments to the ceramic weldment. Forming the upper wall using the subtractive manufacturing technique may limit the requisite level of skill required to fabricate the ceramic weldment, limiting (or eliminating) tendency of the skill level of the fabricators employed to make the ceramic weldment to constrain ceramic weldment fabrication capability. And, in examples wherein the ceramic weldment is employed to deposit materials onto substrates using external devices optically coupled through wall of ceramic weldment, forming the upper wall of the ceramic weldment using the subtractive manufacturing technique may limit variation within the deposited material layers by limiting (or eliminating) dimensional and/or optical property variation potentially imparted into the ceramic weldment by the welding process otherwise employed to attach rib segments to the ceramic weldment.

The term “about” is intended to include the degree of error associated with measurement of the particular quantity based upon the equipment available at the time of filing the application. Operations, to the extent shown and described herein in a specific order in an encompassing method, may be altered in terms of the ordering shown and described herein, and remain within the scope of the present disclosure. Moreover, the methods encompassing the operations shown and described herein may include additional operations and/or exclude certain operations shown and described herein, and remain within the scope of the present disclosure.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

1. A chamber body, comprising:
a ceramic weldment including:
an upper wall;
a sidewall coupled to the upper wall by a sidewall-to-upper wall weld;
a lower wall plate coupled to the sidewall by a sidewall-to-lower wall weld, the lower wall plate defining a passthrough;
a lower wall rib segment coupled to the lower wall plate by a lower wall rib segment weld; and
wherein the upper wall has an upper wall plate portion and an upper wall rib portion defining an upper wall unwelded ribbed region overlaying the passthrough and formed from a singular ceramic workpiece using a subtractive manufacturing technique.

2. The chamber body of claim 1, wherein the upper wall unwelded ribbed region is separated from the passthrough by an interior of the ceramic weldment.

3. The chamber body of claim 1, wherein the upper wall unwelded ribbed region is separated from the passthrough by an interior of the ceramic weldment.

4. The chamber body of claim 1, wherein the ceramic weldment further comprises:
an inject end flange coupled to the upper wall plate portion; and
an exhaust end flange coupled to the upper wall plate portion and separated from the inject end flange by the upper wall unwelded ribbed region of the upper wall.

5. The chamber body of claim 4, further comprising a tubulation body coupled to the lower wall plate at the passthrough and separating the inject end flange from the exhaust end flange of the ceramic weldment.

6. The chamber body of claim 4, wherein the inject end flange and the exhaust end flange separate the upper wall unwelded ribbed region of the ceramic weldment from the lower wall rib segment of the ceramic weldment.

7. The chamber body of claim 1, wherein the lower wall rib segment is one of a plurality of lower wall rib segments, the ceramic weldment further comprising:
a plurality of first side rib segments each arranged between the upper wall unwelded ribbed region and the plurality of lower wall rib segments;
a plurality of second side rib segments each arranged between the upper wall unwelded ribbed region and the plurality of lower wall rib segments; and
wherein the upper wall unwelded ribbed region separates the plurality of first side rib segments from the plurality of second side rib segments.

8. The chamber body of claim 7, wherein the lower wall rib segment is one of a plurality of lower wall rib segments, the ceramic weldment further comprising a plurality of lower rib segment welds coupling the plurality of lower wall rib segments to the lower wall plate and separated from the upper wall unwelded ribbed region by the lower wall plate.

9. The chamber body of claim 7, wherein the ceramic weldment further comprises:
an inject end flange coupled to the upper wall plate portion of the upper wall by an inject end flange-to-upper wall plate portion weld;
an exhaust end flange coupled to the upper wall plate portion of the upper wall by an exhaust end flange-to-upper wall plate portion weld; and
wherein the upper wall unwelded ribbed region separates the inject end flange-to-upper wall plate portion weld from the exhaust end flange-to-upper wall plate portion weld without any intervening weld therebetween.

10. The chamber body of claim 1, wherein the sidewall is a first sidewall and the sidewall-to-upper wall weld is a first sidewall-to-upper wall plate portion weld, the ceramic weldment further comprising:
a second sidewall laterally opposite the first sidewall and separating the lower wall plate of the ceramic weldment from the upper wall of the ceramic weldment; and
a second sidewall-to-upper wall plate portion weld coupling the second sidewall to the upper wall plate portion, wherein the upper wall unwelded ribbed region separates the first sidewall-to-upper wall weld from the second sidewall-to-upper wall weld without any intervening weld therebetween.

11. The chamber body of claim 1, wherein the upper wall unwelded ribbed region has a width that is greater than at least 300 millimeters, wherein the ceramic weldment consists essentially of quartz.

12. The chamber body of claim 1, wherein the upper wall unwelded ribbed region overlays the lower wall rib segment weld of the ceramic weldment.

13. A chamber arrangement, comprising:
a chamber body as recited in claim 1, wherein the upper wall unwelded ribbed region has a width that is greater than at least 300 millimeters;
a divider seated within an interior of the chamber body and having a divider aperture;
a substrate support arranged within the divider aperture and supported for rotation about a rotation axis therein; and
wherein the upper wall unwelded ribbed region overlays the substrate support and the divider of the chamber arrangement.

14. The chamber arrangement of claim 13, further comprising a substrate pyrometer supported above the upper wall of the ceramic weldment and along a substrate pyrometer optical axis intersecting the substrate support, wherein the upper wall unwelded ribbed region optically couples the substrate pyrometer to the interior of the ceramic weldment.

15. The chamber arrangement of claim 13, further comprising a chamber pyrometer supported above the upper wall of the ceramic weldment and along a chamber pyrometer optical axis intersecting the substrate support or the divider, wherein the upper wall unwelded ribbed region is optically coupled to the chamber pyrometer.

16. The chamber arrangement of claim 13, further comprising a plurality of upper heater elements supported above the upper wall of the ceramic weldment, wherein the upper wall unwelded ribbed region optically couples the upper heater elements to the substrate support or the divider of the chamber arrangement.

17. A semiconductor processing system, comprising:
a chamber arrangement including a chamber body recited in claim 1, wherein the upper wall unwelded ribbed region of the ceramic weldment has a width that is greater than at least 300 millimeters;
a precursor source including a silicon-containing material layer precursor coupled to an injection end of the chamber body; and
an exhaust source including a vacuum pump coupled to an exhaust end of the chamber body and therethrough to the precursor source.

18. A method of making a ceramic weldment, comprising:
forming an upper wall having an upper wall plate portion and an upper wall plate portion and an upper wall rib portion extending from the upper wall plate portion from a singular ceramic workpiece using a subtractive manufacturing technique;
coupling a sidewall to the upper wall with a sidewall-to-upper wall weld;
coupling a lower wall plate defining a passthrough to the sidewall using a sidewall-to-lower wall weld such that the upper wall unwelded ribbed region overlays the passthrough; and
coupling a lower wall rib segment to the lower wall plate using a lower wall rib segment weld.

19. The method of claim 18, further comprising:
coupling an inject end flange to the upper wall plate portion of the upper wall using an inject end flange-to-upper wall plate portion weld;
coupling an exhaust end flange to the upper wall plate portion of the upper wall using an exhaust end flange-to-upper wall plate portion weld;
coupling a plurality of first side rib segments to the ceramic weldment using a plurality of first side rib segment-to-ceramic weldment welds; and
coupling a plurality of second side rib segments to the ceramic weldment using a plurality of second side rib segment-to-ceramic weldment welds.

20. The method of claim 18, further comprising:
registering a tubulation body to the passthrough defined within the lower wall plate; and
coupling the tubulation body to the lower wall plate at the passthrough using a tubulation body-to-lower wall plate weld.

21. The method of claim 18, wherein the subtractive manufacturing technique includes one or more of milling, core-drilling, and sawing.

22. A chamber arrangement for a semiconductor processing system having a chamber body made using the method of claim 18.
